(19) United States
(12) Patent Application Publication
(10) Pub. No.: US 2005/0031141 A1
(43) Pub. Date: Feb. 10, 2005

(54) Timer ramp-up circuit and method for a sound masking system

(75) Inventors: Daniel McCrackin, Hamilton (CA); Niklas Moeller, Oakville (CA)

Correspondence Address: MERCHANT & GOULD PC, P.O. BOX 2903, MINNEAPOLIS, MN, 55402-0903, US

(73) Assignee: 777388 Ontario Limited

(21) Appl. No.: 10/634,228

(22) Filed: Aug. 4, 2003

(51) Int. Cl. H04R 3/02; H03G 3/00

(52) U.S. Cl. 381/104; 381/73.1

(57) ABSTRACT

A volume ramp-up circuit for a sound masking system to ramp the volume of the sound masking output from an initial setting to a final volume setting over a ramp-up period. The sound masking system generates a volume setting signal for the ramp-up circuit. The volume ramp-up circuit generates a volume setting signal for the sound masking system based on the volume setting signal and an internally generated control signal. The control signal is stored in non-volatile memory. In the event of a power loss, the setting for the control signal is retrieved from the non-volatile memory and the volume ramp-up for the sound masking system is continued.

### FIELD OF THE INVENTION

The present invention relates to sound masking systems and more particularly to a start timer circuit and method for a sound masking system.

### BACKGROUND OF THE INVENTION

Sound masking systems are widely used in offices and similar workplaces where an insufficient level of background sound results in diminished speech and conversational privacy. Such environments suffer from a high level of noise distractions, and lower comfort levels from an acoustic perspective. Sound masking systems operate on the principle of masking which involves generating a background sound in a given area. The background sound has the effect of limiting the ability to hear two sounds of similar sound pressure level and frequency simultaneously. By generating and distributing the background noise in the given area, the sound masking system masks or covers the propagation of other sounds in the area and thereby increases speech privacy, reduces the intrusion of unwanted noise, and improves the general acoustic comfort level in the area or space.

Sound masking systems are of two main types: centrally deployed systems and independent self-contained systems. In a centrally deployed system, a central noise generating source supplies a series of loudspeakers installed throughout the physical area or space to be covered. The independent self-contained system comprises a number of individual self-contained sound masking units which are installed in the physical space. The sound masking units operate independently of each other, but may include a number of satellite speakers which extend the range of each self-contained, i.e. master, sound masking unit. Most sound masking systems include the capability for broadcast announcements and music over the loudspeakers contained in the sound masking units.

The primary goal of sound masking systems is to provide an unobtrusive, effective masking sound that is adjustable for maximum consistency, and offers the ability to meet the requirements of the occupants. The masking output is preferably sufficient to accommodate the existing acoustic requirements of the workplace environment and adjustable to handle changes to the acoustic characteristics of environment which occur over time.

It will be appreciated that the masking signal comprises a background sound, and that the masking signal is adjusted to provide the optimal sound masking characteristics. Adjustment of the masking signal comprises adjusting the volume and frequency spectrum characteristics.

It is generally not desirable to simply turn on the sound masking system at the full operating volume level as the addition of a full volume sound masking signal will be noticeable to the occupants of the space and may also be disruptive. This disruption will continue until the occupants become accustomed to the background sound level with the effect that the sound masking signal melds into the background.

Accordingly, there remains a need for a system and technique for controlling the introduction of sound masking signals into an acoustic environment.

### BRIEF SUMMARY OF THE INVENTION

The present invention provides a timer or ramp-up circuit and method suitable for use in a sound masking system.

In one aspect, the present invention provides a circuit for controlling volume ramp-up of a sound masking signal in a sound masking system, said circuit comprising: an input port for receiving an external volume control signal; a component for generating an internal volume control signal; a component for storing the internal volume control signal in a non-volatile memory; a component for generating the volume control signal based on the external volume control signal and the internal volume control signal; and an output port for outputting a volume control signal to the sound masking system.

In another aspect, the present invention provides a volume ramp-up circuit for a sound masking output signal in a sound masking system, the volume ramp-up circuit comprises: an input port for receiving an external signal; a controller having a component for generating an internal control signal; a non-volatile memory operatively coupled to the controller; the controller including a component for changing the internal control signal; the controller including a component for storing the internal control signal in the non-volatile memory; the controller including a component for generating a volume signal for controlling the volume of the sound masking output signal, the volume signal being based on the external signal and the internal control signal; an output port coupled to the controller for outputting the volume signal to the sound masking system.

In a further aspect, the present invention provides a method for ramping a sound masking output signal to a desired volume level in a sound masking system, the method comprising the steps of: inputting a volume signal from the sound masking system; generating a control signal from an initial setting; storing the control signal in non-volatile memory; generating a volume output signal for the sound masking output signal, the volume output signal being based on the volume signal and the control signal; outputting the volume output signal to the sound masking system.

In yet another aspect, the present invention provides a sound masking system comprising: a sound masking module for generating a sound masking signal; a volume ramp-up circuit for ramping the sound masking signal from an initial volume setting to a final volume setting; a sound masking module having an output for a volume setting signal; a volume ramp-up circuit having an input coupled to the output for receiving the volume setting signal; the volume ramp-up circuit including a controller, the controller having a component for generating a control signal; the volume ramp-up circuit including non-volatile memory and the controller including a component for storing the control signal in the non-volatile memory; the controller including a component for generating a volume ramp signal, the volume ramp signal being based on the control signal and the volume setting signal; the sound masking module having an input for receiving the volume ramp signal, and the sound masking module being responsive to the volume ramp signal for setting a volume level for the sound masking signal.

Other aspects and features of the present invention will become apparent to more ordinarily skilled in the art upon review of the following description of specific embodiments of the invention in conjunction with the accompanying figures.

### BRIEF DESCRIPTION OF THE DRAWINGS

Reference is now made to the accompanying drawings which show by way of example embodiments of the present invention and in which:

FIG. 1 shows in block diagram form a sound masking system suitable for utilizing a timer circuit and method according to the present invention;

FIG. 2 shows in block diagram form the masking central volume control unit of FIG. 1 incorporating a timer circuit in accordance with the present invention;

FIG. 3 shows in schematic form a circuit implementation of the timer circuit according to the present invention; and

FIG. 4 shows in flow chart form an operational process for the timer or ramp-up circuit according to the present invention.

### DETAILED DESCRIPTION OF THE INVENTION

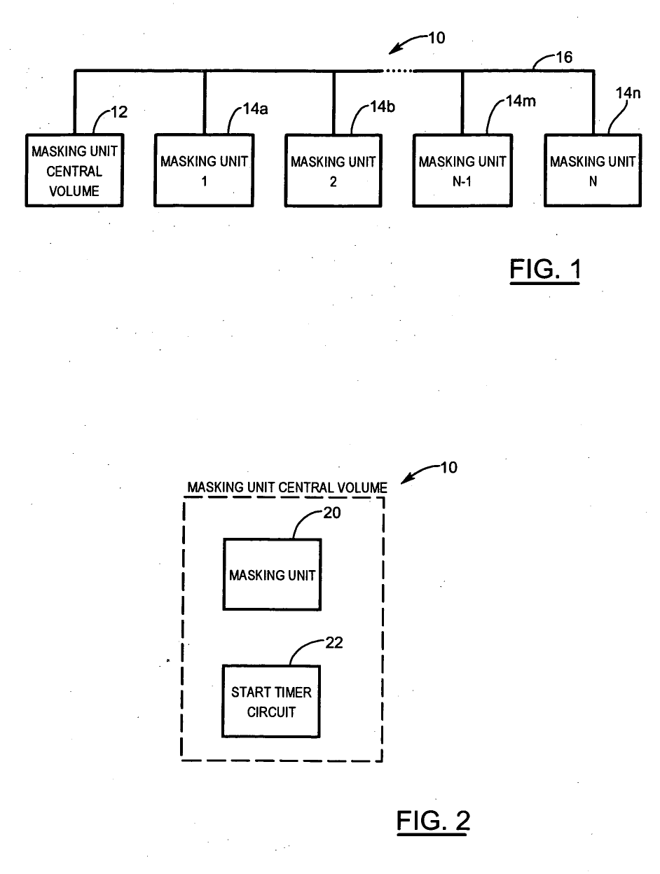

Reference is made to FIG. 1 which shows a sound masking system 10. The sound masking system 10 comprises a masking volume control unit 12 and a number of sound masking units 14, indicated individually as 14a, 14b, . . . 14m, 14n. The sound masking units 14 are coupled to the masking control unit 12 through a bus 16 and are individually addressable. In another embodiment, one sound masking unit 14 is coupled to the masking volume control unit 12 via a hardwired connection. In this embodiment, the sound masking units 14 receive and respond to volume control signals from the masking volume control unit 12. The volume control signals from the masking volume control unit 12 adjust the volume level for the sound masking signal emitted by each of the sound masking units 14.

Reference is next made to FIG. 2 which shows the masking volume control unit 12 in more detail. The masking control unit 12 includes a masking unit 20 and a ramp-up or timer circuit 22. The masking unit 20 provides the functionality associated with sound masking including control and generation of an incoherent sound signal for producing the sound masking. The timer circuit 22 provides start timer operation functions as will be described in more detail below. The timer circuit 22 works in conjunction with the masking unit 20 as will also be described below.

In operation, the timer or ramp-up circuit 22 functions to provide a timed factory test mode and a normal operation mode. In factory test mode, the masking unit 20 is tested over the entire operational volume range. During normal operation mode, the timer circuit 22 generates an analog output that is a function of an analog input control signal and an internally generated volume level. According to one aspect, the internal volume level starts at an initial level and is increased to a final or setting level over a predetermined time period. If power is interrupted, operation resumes at the same internal volume level as when power failed. In this way, the volume level of the sound masking system is ramped up to the full level over a period of time thereby allowing occupants in the space to acclimatize to the sound masking signal which then becomes a part of the ambient sound for their space.

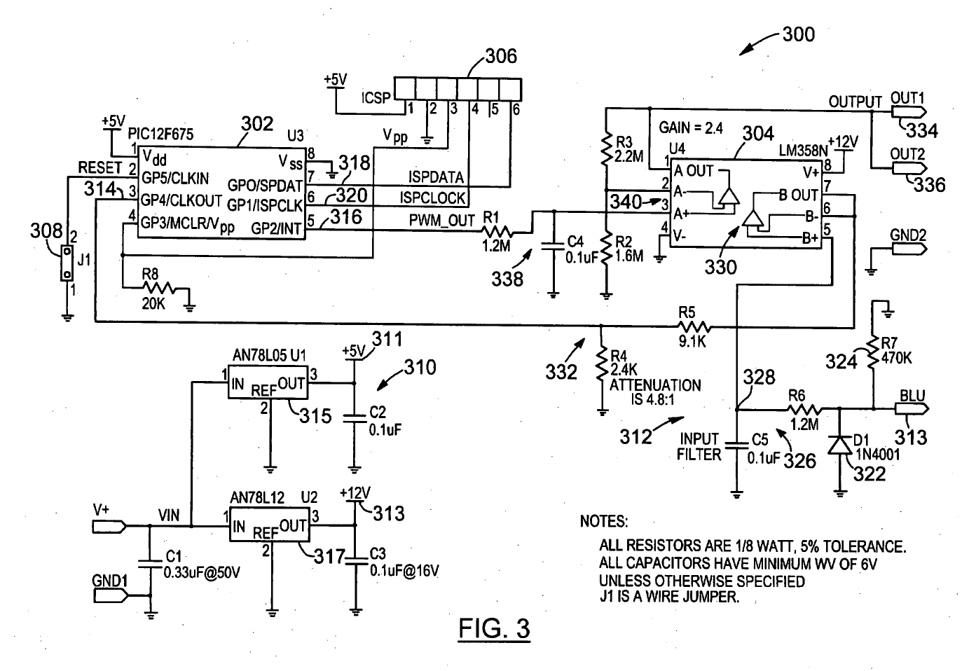

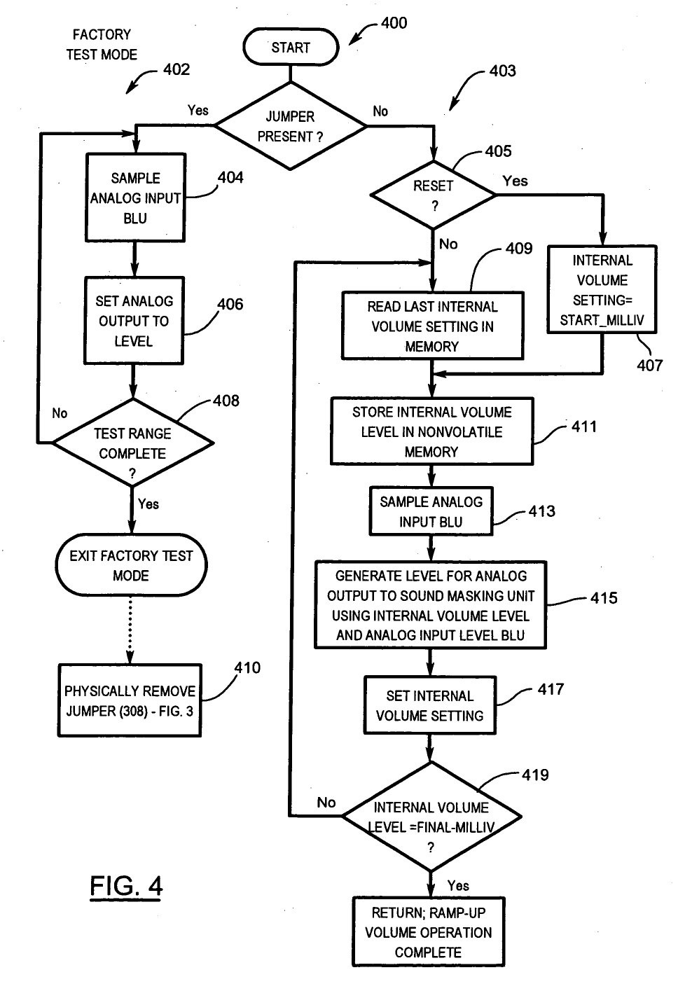

Reference is now made to FIG. 3 which shows an implementation of a circuit for the timer indicated generally by reference 300. The timer circuit 300 comprises a controller 302, a dual operational amplifier circuit 304, a digital signal connector 306, a jumper 308, a power supply circuit 320, and an analog input circuit 312.

The controller 302 is implemented using a PIC microprocessor or microcontroller. The PIC controller 302 includes on-chip program memory EEPROM, data memory RAM and non-volatile data memory EEPROM. In the context of the start timer circuit 22, the PIC controller 302 is configured with an analog input 314, a digital (PWM) output 316, a digital data input 318, and a digital clock input 320. The PIC controller 320 includes an internal clock generator which runs at 4 MHZ.

As shown in FIG. 3, the analog input 314 is coupled to the output of the analog input circuit 312. The analog input circuit 312 receives an input volume signal BLU on input 313. The analog input circuit 312 includes a clamping diode 322, a pull-down resister 324, and a RC filter 326. The input volume signal BLU is clamped by the diode 322 to prevent the signal from going more than 0.7V negative. The clamped input volume signal is pulled down by the resister 324 so that the analog input circuit 312 appears as a SCAMP™PLM module (not shown). The input signal is then filtered by the RC filter 326 which has a 0.12 second time constant. The filtered input signal appears at output 328 which is coupled to a buffer 330. The buffer 330 comprises a non-inverting unity gain amplifier using one of the operational amplifiers as the dual amplifier circuit 304. A voltage divider 332 comprising resisters R4 and R5 is coupled between the output of the buffer 330 and the analog input 314 in the PIC controller 302. When powered from a 12V rail, the dual op amp circuit 304 (the buffer 330) produces an output in the range 0 to 12V. For the PIC controller 302, the voltage divider 332 reduces the range to 0-2.5V at the analog input port 314. This range gives an analog to digital converter output for the PIC controller 302 in the range 0 . . . 127 (i.e. 128 steps) which can be directly mapped to the PWM output 316 range of 0 . . . 127 (128 steps) without further calculations.

The digital PWM output 316 is generated under firmware control in the PIC controller 302 and is used to generate two analog output signals OUT1 and OUT2 on analog outputs 334 and 336, respectively. The analog signals OUT1 and OUT2 control the volume and provide a ramp-up function in the masking unit 20 in the masking control unit 10 (FIGS. 1 and 2).

As shown in FIG. 3, the digital PWM output 316 is passed through a RC filter circuit 338. The RC filter circuit 338 comprises a resister R1 and a capacitor C4 having component values to provide a time constant of 0.12 seconds. The output of the RC filter circuit 338 comprises an analog signal which is applied to a non-inverting amplifier 340. The non-inverting amplifier 340 is implemented using the other operational amplifier in the dual amplifier chip 304. The non-inverting amplifier 340 is configured using resisters R2 and R3 to give a gain of 2.4. With the dual amplifier chip 304 running on the 12V rail, the 2.4 gain transforms the range of the analog output signals OUT1 and OUT2 to 0 to 12V.

As shown in FIG. 3, the power supply circuit 310 generates a +5V rail 311 and a +12V rail 313. The +5V rail 311 is generated using a 5-volt regulator 315 which regulates an input voltage V+. The +12V rail 313 is generated using a 12-volt regulator 317. The input voltage V+is filtered using a capacitor C1, similarly, the +5V rail 311 and the +12V rail 313 are filtered using capacitors C2 and C3, respectively. The +5V rail 311 powers the PIC controller 302 and the +12V rail 313 powers the dual op-amp chip 304.

The digital signal connector 306 comprises an ICSP header and allows in-circuit programming of the PIC controller 302. The ICSP header 306 has an ISO data input 307 which is connected to the data input 318 in the PIC controller 302. The ICSP header 306 also includes an ISP clock input 309 which is connected to the clock input 320 in the PIC controller 302. The ICSP header 306 also includes a programming voltage output 321 which is connected to pin 4 of the PIC controller 302. To re-program the PIC controller 302, i.e. download a new firmware program into the EEPROM program memory, a programming voltage Vpp is applied to pin 4 and firmware data is clocked into the PIC controller 302 on the data input 307 using the clock input 309. For some applications, e.g. where program upgrades are not contemplated, the ISCP header 306 may be omitted from the circuit 300.

The jumper 308 allows the start timer circuit 300 to operate either in factory test mode or in normal volume vamp-up mode. The jumper 308 is cut (or not installed) to operate in normal volume ramp-up mode. In most applications, the jumper 308 is cut after the sound masking system is installed.

In factory test mode, the PIC controller 302 executes a firmware routine which samples the analog input BLU, and which sets the analog output OUT1 (and OUT2) to the same voltage level. This allows the timer circuit 22 (FIG. 2) and the masking unit 20 (FIG. 2) to be tested over the entire operational range for the sound masking output volume. For a previously installed timer circuit board 300, reconnecting a jumper across the terminals for the jumper 308 for more than 1 second with power (+5V) applied resets the PIC controller 302.

With the jumper 308 cut or disconnected, the start-circuit 300 operates in normal mode. In normal mode, the start timer circuit 300 generates the analog outputs OUT1 and OUT2 as a function of the analog input BLU and an internal volume level generated internally by the PIC controller 302. According to this aspect, the internal volume level starts at START_MILLIV (e.g. 4500 mV) and reaches a final level FINAL_MILLIV ( e.g. 0 mV) after a predetermined period measured in minutes TOTAL_MINUTES.

The analog signals OUT1 (and OUT2) are determined as follows:
Analog output (OUT1, OUT2)=12.0−(12.0−analog input (BLU))*(120−Internal volume level)/12.0

The internal volume level is gradually raised or ramped to a final level denoted by FINAL_MILLIV. Each change, i.e. increment or ramped change, in the internal volume level is recorded in the EEPROM by the PIC controller 302. If the timer circuit 22 (or the sound masking system 10) loses power, then the last used internal volume level is retrieved from the EEPROM memory in the PIC 302, and operation is resumed at the internal volume level when power was lost. Once the final volume level FINAL_MILLIV is reached, no further volume changes are made by the PIC 302 under firmware control. For example, if FINAL_MILLIV is represented by zero (0), then when the internal volume level is FINAL_MILLIV, the start timer circuit 300 passes the analog input voltage 313 (BLU) to the analog output 334 (OUT1) and 336 (OUT2).

The start timer circuit 22 is reset to the initial internal volume level START_MILLIV by connecting the jumper 308 for at least one second.

Reference is next made to FIG. 4 which shows in flowchart form operational steps for the timer circuit 300 (FIG. 3) indicated generally by reference 400. The operational steps 400 are performed by the PIC 302 (FIG. 3) under the control of computer code in the form of firmware stored in on-chip program memory, i.e. an EEPROM (not shown). The programming of the controller 302 to perform the functionality as described and depicted in FIG. 4. is within the understanding of those skilled in the art. It is also to be appreciated that while described in the context of firmware control, the functionality of the timer circuit 300 may also be implemented in hardware or a logic array such as a FPGA (Field Programmable Gate Array).

As shown in FIG. 4, the firmware operates in factory test mode 402 or in normal operational mode 403. The mode of operation is determined by the jumper 308 (FIG. 3). If the jumper 308 is present, the firmware operates the PIC controller 302 in the factory test mode. The first step in factory test mode 402 as indicated by block 404 involves sampling the analog input 313 or BLU (FIG. 3). The PIC controller 302 sets the analog outputs 334 or OUT1 and 336 or OUT2 (FIG. 3) to the same voltage level in step 406. The timer circuit 22 and the sound masking unit 20 are then tested for the current signal level on the analog input 313 (BLU). The level on the analog input 313 is then changed step 406 and the sampling operation in step 404 and the setting of the analog outputs 334 and 336 is repeated in step 406. This process is repeated until the entire or a selected range of analog input levels are applied as determined in step 408. Typically, the jumper 308 (FIG. 3) is removed (block 410) in the factory once the factory test mode 402 is completed.

For normal operation mode 403, the jumper 308 (FIG. 3) is cut or removed at the factory, for example after the factory test mode 402 is completed. As shown in FIG. 4, the internal volume level is set to the initial value of START_MILLIV in response to a reset as indicated by blocks 405 and 407. Connecting the jumper 308 (FIG. 3) coupled to the GPS port on the PIC controller 302. The reset may be processed as an interrupt or by polling the port coupled to the jumper 308. If there is no reset, the last (or current) internal volume level is read from non-volatile memory (i.e. EEPROM) as indicated in block 409. For example, START_MILLIV may be set at 4500 MilliVolts and decremented to a final value of zero volts in FINAL-MILLIV. The new value for the internal volume level is stored in the EEPROM in step 411. The next step in block 413 involves sampling the voltage level on the analog input BLU (FIG. 3). Next using the internal volume level and the sampled analog input BLU, a voltage for the analog output OUT1 (FIG. 3) is generated as indicated in block 415. The voltage in the analog output OUT1 is used by the sound masking unit 20 (FIG. 2) to generate the volume level for the sound masking output signal. Next in block 417, the internal volume level is set to the next value. Next the internal volume level setting is compared to the final level setting given by parameter FINAL_MILLIV (block 419). If not equal to FINAL_MILLIV (e.g. 0V), then the steps 409 to 417 are repeated until the final volume setting is reached. For each setting of the analog output OUT1, the sound masking signal is maintained for a predetermined period to provide a suitable acclimatization period for the users before the masking signal is increased to the next level by generating the next voltage level for the analog output OUT1. If during the ramp-up period for the sound masking unit 20 power is lost, then when power is regained in normal mode of operation 403, the last or current value for the internal volume setting is read from non-volatile memory in step 409 and the ramp-up function continues with processing steps 411 to 419 as described above.

The present invention may be embodied in other specific forms without departing from spirit or essential characteristics thereof. Certain adaptations and modifications of the invention will be obvious to those skilled in the art. Therefore, the presently discussed embodiments are considered to be illustrative and not restrictive, the scope of the invention being indicated by the appended claims rather than the foregoing description, and all changes which come within the meaning and range of equivalency of the claims are therefore intended to be embraced therein.

1. A circuit for controlling volume ramp-up of a sound masking signal in a sound masking system, said circuit comprising:
an input port for receiving an external volume control signal;
a component for generating an internal volume control signal;
a component for storing said internal volume control signal in a non-volatile memory;
a component for generating said volume control signal based on said external volume control signal and said internal volume control signal; and
an output port for outputting a volume control signal to the sound masking system.

2. The circuit as claimed in claim 1, further including a component for changing the level of said internal volume control signal over a range to a final level.

3. The circuit as claimed in claim 1, further including a component for retrieving said internal volume control signal from said non-volatile memory in response to a power loss condition, and using said retrieved internal volume control signal to generate said volume control signal.

4. The circuit as claimed in claim 2, wherein said component for generating an internal volume control signal comprises a component for setting the internal volume control signal to an initial setting and a component for changing the internal volume control signal in steps from said initial setting to a final setting.

5. The circuit as claimed in claim 4, wherein said final setting corresponds to a final volume setting for the sound masking signal.

6. The circuit as claimed in claim 4, wherein said component for generating said volume control signal utilizes an equation as follows:
volume control signal=C1−(C1−external volume control signal)*(C2−internal volume control signal)/C1
wherein C1 and C2 are constants.

7. The circuit as claimed in claim 6, wherein said initial setting is approximately 4500 millivolts and said final setting is approximately 0 millivolts, and said constant C1 is approximately 12 and said constant C2 is approximately 120.

8. A volume ramp-up circuit for a sound masking output signal in a sound masking system, said volume ramp-up circuit comprising:
an input port for receiving an external signal;
a controller having a component for generating an internal control signal;
a non-volatile memory operatively coupled to said controller;
said controller including a component for changing said internal control signal;
said controller including a component for storing said internal control signal in said non-volatile memory;
said controller including a component for generating a volume signal for controlling the volume of the sound masking output signal, said volume signal being based on said external signal and said internal control signal;
an output port coupled to said controller for outputting said volume signal to the sound masking system.

9. The volume ramp-up circuit as claimed in claim 8, wherein said controller includes a component for reading said internal control signal from said non-volatile memory in response to a power loss, and said read internal control signal being used with said external signal to generate said volume signal.

10. A method for ramping a sound masking output signal to a desired volume level in a sound masking system, said method comprising the steps of:
inputting a volume signal from the sound masking system;
generating a control signal from an initial setting;
storing said control signal in non-volatile memory;
generating a volume output signal for the sound masking output signal, said volume output signal being based on said volume signal and said control signal;
outputting said volume output signal to the sound masking system.

11. The method as claimed in claim 10, wherein the step for generating a control signal comprises changing said control signal over a range in steps to a final value.

12. The method as claimed in claim 11, further including the step of recovering said stored control signal from said non-volatile memory and using said control signal with said volume signal to generate said volume output signal.

13. The method as claimed in claim 12, wherein said step of generating a volume output signal comprises determining said volume output signal as follows:
volume output signal=C1−(C1−volume signal)*(C2−control signal)/C1
wherein C1 and C2 comprise constants.

14. The method as claimed in claim 13, wherein said initial setting is approximately 4.5 Volts and said final setting is approximately 0 Volts, and said constant C1 is approximately 12 and said constant C2 is approximately 120.

15. A sound masking system comprising:
a sound masking module for generating a sound masking signal;
a volume ramp-up circuit for ramping said sound masking signal from an initial volume setting to a final volume setting;
said sound masking module having an output for a volume setting signal;
said volume ramp-up circuit having an input coupled to said output for receiving said volume setting signal;
said volume ramp-up circuit including a controller, said controller having a component for generating a control signal;
said volume ramp-up circuit including non-volatile memory and said controller including a component for storing said control signal in said non-volatile memory;
said controller including a component for generating a volume ramp signal, said volume ramp signal being based on said control signal and said volume setting signal;
said sound masking module having an input for receiving said volume ramp signal, and said sound masking module being responsive to said volume ramp signal for setting a volume level for said sound masking signal.

16. The sound masking system as claimed in claim 15, wherein said controller includes a component for reading said control signal from said non-volatile memory in response to a loss of power to said sound masking module or said volume ramp-up circuit, and said retrieved control signal being used with said volume setting signal to generate said volume ramp signal for said sound masking module.
